(19) United States
(12) Patent Application Publication
(10) Pub. No.: US 2003/0030573 A1
(43) Pub. Date: Feb. 13, 2003

(54) Morphology-based text entry system

(76) Inventor: Michael J. Ure, Cupertino, CA (US)

Correspondence Address: Michael J. Ure, 10518 Phil Place, Cupertino, CA, 95014, US

(21) Appl. No.: 09/829,599

(22) Filed: Apr. 9, 2001

(51) Int. Cl. H03M 11/00; H03K 17/94

(52) U.S. Cl. 341/22

(57) ABSTRACT

The present invention, generally speaking, provides a text entry system that uses a relatively small number of keys and that is well-adapted to memorization and skill-building. In one aspect of the invention, the text entry system is based on a set of well-chosen, “morphologically significant” symbols, related in pairs, with one such symbol assigned per key. A letter is entered unambiguously by sequentially pressing multiple keys, preferably exactly two keys. In another aspect of the invention, the number of symbols in the set is fewer than the number of keys in a telephone keypad. “Extra” keys are assigned to other characters or actions, such as “space,” “period,” backspace,” and return. Different modes of operation are provided, allowing for the entry of numbers, the entry of punctuation, cursoring, etc.

### BACKGROUND OF THE INVENTION

1. Field of the Invention

The present invention relates to text entry systems.

2. State of the Art

Various manual text entry systems (excluding voice recognition) have emerged to address the need presented by increasing miniaturization. The telephone keypad has been used for many years for text entry. In one such system, the keys are each labeled with three letters of the alphabet, and a particular letter is entered by pressing a key once, twice or three times, corresponding to the order of the desired letter among the three, hence requiring on average two key presses per letter. Text entry using this method is rather laborious; among other reasons, the locations of the various letters on the keys are not easily remembered from one use to the next.

In the Tegic T9 (TM) input system, a similar arrangement is used. However, disambiguation software is used such that a only a single press per desired letter is required. For numbers and symbols, a menu key is provided. Pressing the key causes a menu including a symbols entry and a numbers entry to appear. The user cursors to the desired entry using dedicated cursor keys, then presses the menu key again to select. For numbers, the user presses the corresponding number key(s). For symbols, a “map” is displayed giving a correspondence between a set of symbols and the number keys.

Alternatively, some devices incorporate a miniature QUERTY-like keyboard having keys that are comparatively tiny. If the layout is QUERTY-based, one having some keyboarding skill may locate a desired letter relatively quickly. Effectiveness is increased where the keys of different halves of the keyboard are operated by opposite ones of the user's thumbs, as in the Blackberry (TM) device from Research in Motion (RIM). Even so, manipulation of the tiny keys remains rather laborious.

Other approaches dispense with keying altogether, in favor of stylus input. Examples include the now-discontinued Apple Newton (TM) PDA and the Palm (TM) connected organizer. In the case of the Newton, a “natural” handwriting recognition approach is followed where text is written where it is to appear, using either printing or cursive writing. Such an approach is not well-suited to increasing miniaturization. In the case of the Palm organizer, “unistroke” characters are entered in a separate text entry area using the Graffiti (TM) text entry system. Some continuity of writing is sacrificed, and a stylus is of course required.

A text entry system is desired that does not require a stylus or the manipulation of tiny keys. A text entry system is also desired that is more versatile and more easily remembered from use to use than existing telephone keypad systems, such that an increasing skill level may be built up.

### SUMMARY OF THE INVENTION

The present invention, generally speaking, provides a text entry system that uses a relatively small number of keys and that is well-adapted to memorization and skill-building. In one aspect of the invention, the text entry system is based on a set of well-chosen, “morphologically significant” symbols, related in pairs, with one such symbol assigned per key. A letter is entered unambiguously by sequentially pressing multiple keys, preferably exactly two keys. In another aspect of the invention, the number of symbols in the set is fewer than the number of keys in a telephone keypad. “Extra” keys are assigned to other characters or actions, such as “space,” “period,” backspace,” and return. Different modes of operation are provided, allowing for the entry of numbers, the entry of punctuation, cursoring, etc.

### BRIEF DESCRIPTION OF THE DRAWING

The present invention may be further understood from the following description in conjunction with the appended drawing. In the drawing:

FIG. 1 is a plan diagram of a keypad layout in accordance with one aspect of the present invention;

FIG. 2 is a table setting forth for each letter of the alphabet a corresponding key combination;

FIG. 3 is a plan diagram of another keypad layout;

FIG. 4 is a plan diagram of another keypad layout; and

FIG. 5 is a block diagram of a hardware arrangement with which the present invention may be used.

### DETAILED DESCRIPTION OF THE PREFERRED EMBODIMENTS

The preferred embodiments of the invention will now be described, readily susceptible to myriad variations based on the principles described herein.

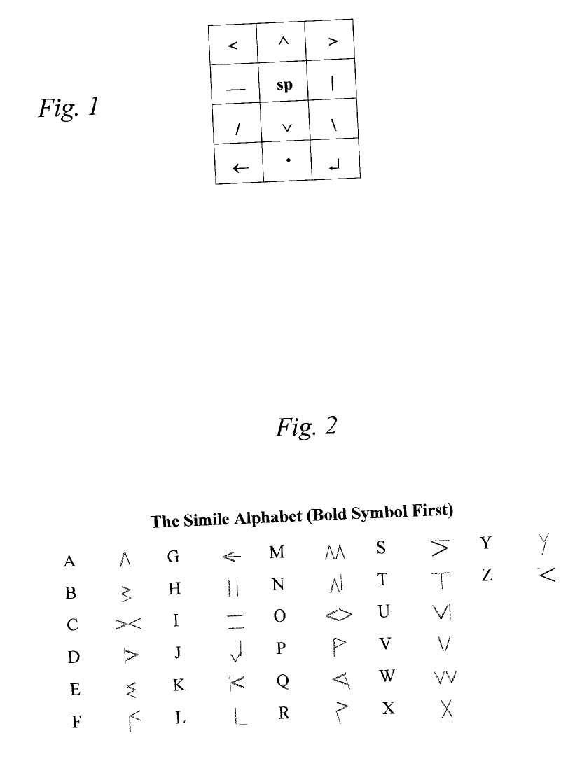

Referring to FIG. 1, a diagram is shown of a keypad layout in accordance with an exemplary embodiment of the invention. The “keys” may be electro-mechanical or may be purely electrical—i.e., touch keys. Furthermore, the indicia appearing on the keys may be fixed or variable (variable, for example, in the case of touch keys overlying a display). Although the invention principally contemplates activation of the keys by direct touch, activation may also be performed using a stylus.

The keys preferably correspond in layout to those of a telephone keypad. In one embodiment, the keys are about 0.375″ high and about 0.5″ wide, although the size of the keys may be larger or smaller. In the same embodiment, there is no space between the keys, but this is not a requirement. (Of course, if ultimate miniaturization is desired, the keys can be made tiny like those of prior art devices, at the cost of reduced user comfort.)

For purposes of the present description, the keys will be identified by column (columns 1-3) and row (rows 1-4), with column number and row number being separated by a “period.”

In the illustrated embodiment, the following indicia or symbols appear on the keys:

TABLE 1

| KEY | SYMBOL | KEY | SYMBOL |
|---|---|---|---|
| 1.1 | < | 3.1 | / |
| 1.2 | | 3.2 | ν |
| 1.3 | > | 3.3 | \ |
| 2.1 | _{—} | 4.1 | ← |
| 2.2 | sp | 4.2 | · |
| 2.3 | \| | 4.3 | [symbol] |

The symbols appearing on keys 2.2, 4.1, 4.2 and 4.3 signify “space,” “backspace,” “period,” and “return,” respectively.

The remaining eight symbols form a set of well-chosen, “morphologically significant” symbols, related in pairs, including the following pairs: <, >;_, |; /, \; and [symbol] , [symbol] .

Although the present text entry system is applicable to a variety of languages and alphabets, it application to the English alphabet will be described. Every letter of the English alphabet is assigned a unique symbol or combination of symbols. Referring to FIG. 2, in a preferred embodiment, each letter is assigned a two-symbol combination. The foregoing combinations are exemplary:

TABLE 2

| | Combi- | | Combi- | | Combi- | | Combi- |
|---|---|---|---|---|---|---|---|
| Letter | nation | Letter | nation | Letter | nation | Letter | nation |
| A | /, \ | H | \|, \| | O | <, > | V | \, / |
| B | >, > | I | _, _{—} | P | \|, > | W | ν, ν |
| C | >, < | J | \|, ν | Q | <, \ | X | ν, |
| D | >, \| | K | <, \| | R | >, \ | Y | ν, / |
| E | <, < | L | \|, _{—} | S | _, > | Z | _, < |
| F | \|, < | M | , | T | _, \| | | |
| G | <, _{—} | N | , \| | U | ν, \| | | |

Many other different combinations are possible. Preferably, however, the combinations are suggestive of the form of the printed capital letter, as illustrated in FIG. 2. This feature is made possible by the choice of “morphologically significant” symbols. Note that many possible symbols combinations are unused in the foregoing assignments. These may be assigned for other purposes, including text entry, control, etc.

The layout of FIG. 1 and the assignments of FIG. 2 are particularly advantageous where the keys are to be operated by alternating use of thumbs (as in the case of the Blackberry device, for example). Most letter are signified using only the keys of columns 1 and 3, the keys of column 1 being operated by the left thumb and the keys of column 3 being operated by the right thumb; the “space” key is centrally located; and there is a natural opposition between the symbols of each pair, aiding memorization and the acquisition of skill. Greater locality of motion is achieved, this being the hallmark of touch typing ability.

Capitalization, numerics, punctuation, cursoring, etc., may be provided for in many different ways. One way, of course, it to simply provide additional keys. Assuming that no additional keys are to be provided, there are still many ways of providing the foregoing features.

Capitalization, for example, may be provided by keeping the initial key depressed for a perceptibly longer time than usual. Cap lock and cap unlock may be provided in toggle fashion by simultaneously pressing, for example, the “period” key while inputting the first or last of a series of capital letters.

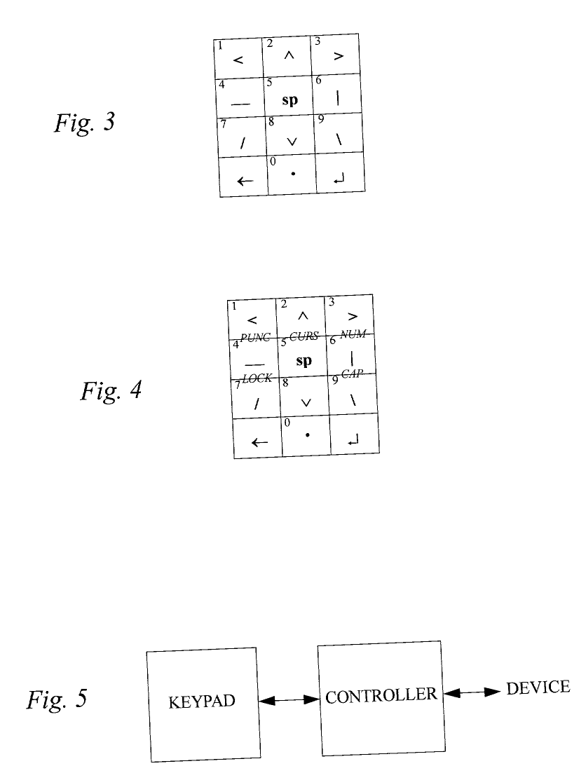

Multiple modes, including a numeric mode, may be provided. Modes may be switched automatically in context-dependent fashion based on device operation. Where manual mode-switching is required, it may be performed, e.g., by pressing key 1.1 for a perceptibly longer duration than normal. In numeric mode, the keys may operate like those of a conventional telephone keypad. FIG. 3 shows another embodiment of the keypad in which numbers are explicitly indicated on the keys.

Punctuation may be provided in many different ways. Where manual mode-switching is required, it may be performed, e.g., by pressing the “period” key for a perceptibly longer duration than normal. Normally, punctuation mode persists for the entry of one punctuation mark, after which text mode automatically resumes.

In punctuation mode, punctuation marks may be indicated, for example, either “morphologically” or by initial letter. Because the morphology of punctuation symbols does not lend itself as well to representation using the chosen symbols, designation by initial letter is presently preferred. For example, to enter a question mark, punctuation mode would first be designated, after which the letter Q would be entered. Where multiple punctuation marks have the same initial letter, the most frequently occurring one is used by default. If this is not correct, the next most frequency punctuation mark beginning with that letter may be substituted by pressing “ [symbol] ,” and so forth, until the correct punctuation mark is displayed. (Here it is assumed that a punctuation mark will not normally be followed with one of the letters having “ [symbol] ” as the initial symbol.)

Cursoring may be performed using the keys bearing the “ [symbol] ”, “ [symbol] ”, “<”, and “>” symbols. Consistent with the foregoing pattern, cursor mode may be entered (or exited) by pressing one of the foregoing keys for a perceptibly longer period of time than normal.

Furthermore, any of various pointing devices may be integrated with the keypad, for example the “pointing stick” popularized by IBM or a miniature track-marble. Such a pointing device may be integrated with or in the vicinity of the “space” key, for example. Alternatively, the space key may be made to operate in similar fashion as a pointing stick. In this instance, a small boundary space is provided around the space key (for example, by making the space key slightly smaller than other keys), and the space key is provided with a “sticky” tactile surface (which also causes the space key to serve as a tactile reference point). The key is adapted to be moved by the finger in any desired direction, allowing for pointing to be performed in similar manner as a pointing stick. However, the basic form of the key remains unchanged and distinct from that of the pointing stick.

Alternatively, one or more keys may be made touch-sensitive, allowing for touch-pad-like operation.

By incorporating a pointing device into the keypad, the present input method becomes well-adapted for mobile web browsing.

An additional technique may be used for web browsing. As previously described, punctuation marks may be entered by entering the initial letter of a desired punctuation mark. In like manner, many web page links will have text associated with them and may be selected in like manner. If multiple links have the same initial letter, these links may be highlighted as a signal to the user to input the next letter in the desired link. Furthermore, from the standpoint of the web page designer, link text may be made conditional on the type of device to which the web page is to be sent such that, if the web page is to be sent to a mobile device, link text may be made visible that might otherwise remain hidden were the web page to be sent to a desktop or laptop machine, for example. This design measure will enhance the usefulness of this manner of mobile device web browsing. The browser is modified to, when a page is received, form a link text table. When character input is received, if a received character corresponds to a unique link text table entry, the link is followed. If the character corresponds to multiple link text table entries, the link text for these entries is highlighted, prompting the user to make a further entry.

An alternative, perhaps more preferable, technique for switching between modes involves pressing multiple keys simultaneously. In one embodiment, adjacent keys of column 1 and column 2 and adjacent keys of column 2 and column 3 may be pressed simultaneously, provided for eight possible different modes. In another embodiment, adjacent keys both within column 1 and adjacent keys both within column 2 may be pressed simultaneously, providing for six different modes. The keys to be pressed to enter or exist a particular mode may be labeled with an indication of that mode, for example PUNC, CAP, LOCK (cap lock/unlock and punctuation lock/unlock), CURS, NUM, etc., as shown in FIG. 4. In one embodiment, the cursor and number modes are persistent, whereas the punctuation and capitalization modes apply to a single entry (unless locked).

In one embodiment, cursor mode continues until the user presses a “non-cursor” key—one that's not <, >, [symbol] , or [symbol] . So, to cursor to a spot and then enter a letter that begins with one of these symbols, it is necessary to backspace first to exit cursor mode, re-enter the deleted character if needed, then enter the desired letter.

FIG. 5 illustrates a generic hardware arrangement with which the present input system may be used. A keypad like that previously described is coupled to a suitable controller. Based on user inputs, the controller forms an output stream that is sent to a device. The output stream may identical to that of a standard keyboard. The behavior of the controller is such as to realize the functions previously described.

It will be appreciated by those of ordinary skill in the art that the invention can be embodied in other specific forms without departing from the spirit or essential character thereof. The presently disclosed embodiments are therefore considered in all respects to be illustrative and not restrictive. The scope of the invention is indicated by the appended claims rather than the foregoing description, and all changes which come within the meaning and range of equivalents thereof are intended to be embraced therein.

What is claimed is:

1. A method of text input comprising:
for each of multiple letters of an alphabet, representing that letter by a sequence of multiple non-alphabetic symbols, the symbols being suggestive of the form of the letter;
a user manually inputting a sequence of said symbols; and
outputting a code designating a corresponding letter.

2. The method of claim 1, wherein the alphabet is the English alphabet, and wherein for a majority of the letters, the sequences of symbols used to represent those letters are as follows:
TABLE 3

| | Combi- | | Combi- | | Combi- | | Combi- |
|---|---|---|---|---|---|---|---|
| Letter | nation | Letter | nation | Letter | nation | Letter | nation |
| A | /, \ | H | \|, \| | O | <, > | V | \, / |
| B | >, > | I | _, _{—} | P | \|, > | W | ν, ν |
| C | >, < | J | \|, ν | Q | <, \ | X | ν, |
| D | >, \| | K | <, \| | R | >, \ | Y | ν, / |
| E | <, < | L | \|, _{—} | S | _, > | Z | _, < |
| F | \|, < | M | , | T | _, \| | | |
| G | <, _{—} | N | , \| | U | ν, \| | | |

3. The method of claim 2, wherein for a substantial portion of the letters, the sequences of symbols used to represent those letters are as stated.

4. The method of claim 1, wherein the symbols appear on keys of a keypad.

5. The method of claim 4, wherein the numbers 0-9 also appear on the keys of the keypad.

6. The method of claim 4, wherein multiple ones of the following modes are provided: text mode; capitalization mode; punctuation mode; numeric mode; and cursor mode.

7. The method of claim 6, further comprising a user switching modes by pressing multiple keys at once.

8. The method of claim 7, wherein the keys are arranged in three columns, and mode-switching is performed by the user pressing two adjacent keys located in adjacent columns.

9. The method of claim 5, wherein a numeric mode is provided in which the user enters a number by pressing a single key.

10. The method of claim 4, comprising a user pressing the keys using the user's thumbs.

11. The method of claim 4, wherein a pointing device is provided in close proximity to the keypad, further comprising the user operating the pointing device.

12. The method of claim 1, wherein the symbols include pairs of symbols of related form.

13. The method of claim 12, wherein the symbols include at least three pairs of symbol.

14. The method of claim 13, wherein the symbols include four pairs of symbols.

15. The method of claim 12, wherein the symbols includes at least one of the following pairs of symbols: <, >;_, |; /, \; and [symbol] , [symbol] .

16. The method of claim 12, wherein the symbols includes multiple ones of the following pairs of symbols: <, >; _, |; /, \; and [symbol] , [symbol] .

17. The method of claim 16, wherein one or more separate keys, on which none of the symbols appears, are assigned one or more of the following functions: space, backspace, period and return.

18. The method of claim 12, wherein the symbols includes a majority of the following pairs of symbols: <, >, _; |, /, \; and [symbol] , [symbol] .

19. The method of claim 12, wherein the symbols includes the following pairs of symbols: <, >; _, |, /, \; and [symbol] , [symbol] .

20. The method of claim 19, wherein symbols of each pair of symbols appear on keys situated within a same row or a same column of the keypad.

21. The method of claim 20, wherein symbols of the pair [symbol] , [symbol] appear on keys situated within the same column.

22. The method of claim 21, wherein symbols of the other pairs of symbols appear on keys situated within the same row.

23. The method of claim 12, wherein symbols of each pair of symbols appear on keys situated within a same row or a same column of the keypad.

24. The method of claim 12, wherein symbols of each pair of symbols appear on non-adjacent keys.

25. The method of claim 24, wherein a key centrally situated on the keypad is assigned the space function.

26. The method of claim 1, wherein capitalization is performed by the user keeping selecting an initial symbol of a sequence of symbols corresponding to a desired letter and keeping the initial symbol selected for a perceptibly longer time than when a corresponding lower-case letter is intended.

27. The method of claim 1, wherein punctuation is performed by entering an initial letter of a name of a desired punctuation mark.

28. A text entry apparatus using a system in which, for each of multiple letters of an alphabet, that letter is represented by a sequence of multiple non-alphabetic symbols, the symbols being suggestive of the form of the letter, comprising:
means for a user to manually input a sequence of said symbols; and
a controller for outputting a code designating a corresponding letter.

29. The apparatus of claim 28, further comprising pointing means, coupled to the controller, for producing a position indication in response to user input.

30. The apparatus of claim 28, wherein the alphabet is the English alphabet, and wherein for a substantial portion of the letters, the sequences of symbols used to represent those letters are as follows:
TABLE 4

| | Combi- | | Combi- | | Combi- | | Combi- |
|---|---|---|---|---|---|---|---|
| Letter | nation | Letter | nation | Letter | nation | Letter | nation |
| A | /, \ | H | \|, \| | O | <, > | V | \, / |
| B | >, > | I | _, _{—} | P | \|, > | W | ν, ν |
| C | >, < | J | \|, ν | Q | <, \ | X | ν, |
| D | >, \| | K | <, \| | R | >, \ | Y | ν, / |
| E | <, < | L | \|, _{—} | S | _, > | Z | _, < |
| F | \|, < | M | , | T | _, \| | | |
| G | <, _{—} | N | , \| | U | ν, \| | | |

31. The apparatus of claim 30, wherein for a majority of the letters, the sequences of symbols used to represent those letters are as stated.

32. The apparatus of claim 30, wherein the symbols appear on keys of a keypad.

33. The apparatus of claim 32, wherein the numbers 0-9 also appear on the keys of the keypad.

34. The apparatus of claim 32, wherein multiple ones of the following modes are provided: text mode; capitalization mode; punctuation mode; numeric mode; and cursor mode.

35. The apparatus of claim 34, further comprising a user switching modes by pressing multiple keys at once.

36. The apparatus of claim 35, wherein the keys are arranged in three columns, and mode-switching is performed by the user pressing two adjacent keys located in adjacent columns.

37. The apparatus of claim 32, wherein a numeric mode is provided in which the user enters a number by pressing a single key.

38. The apparatus of claim 28, wherein the symbols include pairs of symbols of related form.

39. The apparatus of claim 38, wherein the symbols include at least three pairs of symbol.

40. The apparatus of claim 39, wherein the symbols include four pairs of symbols.

41. The apparatus of claim 39, wherein the symbols includes at least one of the following pairs of symbols: <, >; _, |; /, \; and [symbol] , [symbol] .

42. The apparatus of claim 39, wherein the symbols includes multiple ones of the following pairs of symbols: <, >; _, |; /, \; and [symbol] , [symbol] .

43. The apparatus of claim 42, wherein one or more separate keys, on which none of the symbols appears, are assigned one or more of the following functions: space, backspace, period and return.

44. The apparatus of claim 39, wherein the symbols includes a majority of the following pairs of symbols: <, >; _, |; /, \; and [symbol] , [symbol] .

45. The apparatus of claim 39, wherein the symbols includes the following pairs of symbols: <, >; _, |; /, \; and [symbol] , [symbol] .

46. The apparatus of claim 45, wherein symbols of each pair of symbols appear on keys situated within a same row or a same column of the keypad.

47. The apparatus of claim 46, wherein symbols of the pair [symbol] , [symbol] appear on keys situated within the same column.

48. The apparatus of claim 47, wherein symbols of the other pairs of symbols appear on keys situated within the same row.

49. The apparatus of claim 39, wherein symbols of each pair of symbols appear on keys situated within a same row or a same column of the keypad.

50. The apparatus of claim 39, wherein symbols of each pair of symbols appear on non-adjacent keys.

51. The apparatus of claim 50, wherein a key centrally situated on the keypad is assigned the space function.

52. The apparatus of claim 28, wherein capitalization is performed by the user keeping selecting an initial symbol of a sequence of symbols corresponding to a desired letter and keeping the initial symbol selected for a perceptibly longer time than when a corresponding lower-case letter is intended.

53. The apparatus of claim 28, wherein punctuation is performed by entering an initial letter of a name of a desired punctuation mark.

54. A method of following hyperlinks using a compact keyboard, comprising:
displaying a page including one or more hyperlinks; and
activating a desired hyperlink by entering a first letter of display text associated with that hyperlink.
